(19) United States
(12) Patent Application Publication
(10) Pub. No.: US 2008/0031065 A1
(43) Pub. Date: Feb. 7, 2008

(54) SEMICONDUCTOR MEMORY DEVICE WITH COLUMN TO BE SELECTED BY BIT LINE SELECTION SIGNAL

(76) Inventors: Yasuyuki KAJITANI, Fujisawa-shi (JP); Daisuke Kato, Kamakura-shi (JP); Mariko Kaku, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/865,398

(22) Filed: Oct. 1, 2007

Related U.S. Application Data
(62) Division of application No. 11/240,507, filed on Oct. 3, 2005.

(30) Foreign Application Priority Data
Feb. 2, 2005 (JP) 2005-026713

(51) Int. Cl. G11C 7/02

(52) U.S. Cl. 365/208

(57) ABSTRACT

A sense amplifier bank contains sense amplifier circuits, data line pairs and selection circuits. The selection circuits set one of a connection status and a disconnection status between a bit line pair and the data line pair in accordance with a bit line selection signal. A control circuit controls the bit line selection signal supplied to the selection circuits. A global bit line selection signal line is connected to the control circuit, and receives the bit line section signal therefrom. Drive circuits, input portions of which are connected to the global bit line selection signal line, drive the bit line selection signal supplied to the global bit line selection signal line and output it, and the drive circuits are arranged within the sense amplifier bank. A local bit line selection signal line supplies the bit line selection signal driven by the drive circuit to the selection circuit.

### CROSS-REFERENCE TO RELATED APPLICATIONS

This application is a divisional of U.S. application Ser. No. 11/240,507, filed on Oct. 3, 2005 and is based upon and claims the benefit of priority from prior Japanese Patent Application No. 2005-026713, filed Feb. 2, 2005, the entire contents of which are incorporated herein by reference.

### BACKGROUND OF THE INVENTION

1. Field of the Invention

The present invention relates to a semiconductor memory device comprising a column that can be selected by a bit line selection signal.

2. Description of the Related Art

Recent years, the performance of semiconductor memory devices is further advanced, and more specifically, a higher operation speed and a lower consumption power, etc. are being promoted. FIG. 1 shows an example of the circuit diagrams that illustrates the structure of a sense amplifier in a conventional semiconductor memory device. In this figure, an “H” level potential of a word line is indicated by voltage VPP, an “H” level potential of a bit line is indicated by voltage VBLH, an “L” level potential of a bit line is indicated by voltage VBLL, a precharge potential of a bit line is indicated by voltage VBLEQ, a peripheral logic power potential is indicated by VDD and a ground potential is indicated by VSS.

The operation of the above-described semiconductor memory device will now be described with use of a timing chart illustrated in FIG. 2. A bit line precharge signal BLP is a gate signal of a transistor that pre-charges a bit line BL,/BL to a voltage VBLEQ. First, the bit line precharge signal BLP is set from an “H” level (for example, voltage VPP) to a “L” level (for example, ground potential VSS), and thus the precharge on the bit line BL,/BL is released. Consequently, a word line WL is set from the “L” level (for example, ground potential VSS) to the “H” level (for example, voltage VPP), and thus data stored in a respective memory cell appear on the bit line.

After a certain period of time, when an NSA driver activation signal SEN is set from the “L” level (for example, ground potential VSS) to the “H” level (for example, voltage VBLH), and a PSA driver activation signal SEP is set from the “H” level (for example, voltage VBLH) to the “L” level (for example, ground potential VSS), the data appearing on the bit line is amplified. Thus, the bit line on the “H” side is set to the voltage VBLH, and the bit line on the “L” side is set to the voltage VBLL (usually, the ground potential VSS). Then, a bit line selection signal CSL is set from the “L” level (for example, ground potential VSS) to the “H” level (for example, voltage VDD). By transferring data on the bit line BL,/BL a data line DQ,/DQ, the data is read, whereas by transferring data on a data line to a bit line, the data is written. FIG. 2 illustrates the case of writing.

In accordance with the demand for a higher performance of devices (that is, higher operation speed and lower consumption power), the size of elements of a device has been reduced to a fine level based on the scaling rule. Accordingly, the power supply voltage applied to a transistor in a chip of the device has been lowered as the generation succeeded. Since the reduction in size of elements will further advance from now, it is considered that the fall of power supply voltage will be a more significant problem in designing.

As the power supply voltage is lowered, the threshold voltage of the transistor must be lowered. Therefore, in, for example, an SRAM (static random access memory), the increase in cell leakage caused by a fall of threshold voltage will be a problem. Meanwhile, in DRAMs (dynamic random access memories), as the size becomes finer, it is becoming difficult to secure the cell capacitance or to suppress the leak current from a cell. Therefore, when the power potential (high level bit line voltage VBLH) is lowered, the charge amount accumulated in a cell is decreased, thereby deteriorating the data maintaining performance. In order to deal with such a problem, it is expected that the power supply voltage of a memory cell portion should necessarily be set higher than that of the peripheral logic portion. In this case, however, as shown in FIG. 3, those circuits (including a DQ buffer) located outside a pair of data lines DQ,/DQ operate at the same voltage, VDD, as that of the peripheral logic portion, whereas a sense amplifier circuit has to operate at a higher voltage than VDD, that is, VBLH or the like.

In the case where a transistor of a different type from that of the peripheral logic portion is used in a memory cell portion where the power supply voltage is high (note, for example, that a transistor used in the peripheral logic portion operated at a low voltage is characterized by its short gate length, a thin gate oxide film or the like, to achieve a high speed operation), it is necessary in the light of reliability to avoid application of a voltage VBLH that is used for a sense amplifier circuit to the circuits outside a pair of data lines DQ,/DQ. Here, the easiest way of the possible measures is to drive the bit line selection signal CSL at the power potential VDD. However, when data reverse to that held in the sense amplifier circuit is written to the memory cell, in other words, when the data of the bit line pair BL,/BL must be reversed, the data held in the sense amplifier circuit by the voltage VBLH must be reversed by a DQ gate driven by the power potential VDD which is lower than the voltage VBLH. Therefore, it is necessary here to enlarge the size of the transistor that makes up the DQ gate.

FIG. 4 is a diagram showing results of simulation, which indicate a writing speed achieved when the bit line section signal CSL is driven at a voltage lower than that used for the sense amplifier circuit. The horizontal axis indicates the size of the transistor of the DQ gate (gate width), whereas the vertical axis indicates the minimum value of the pulse width of a bit line selection signal CSL necessary to write data. There is not plot found in the range where the size of the DQ gate is less than 3 μm, and this fact indicates that from that point, no matter how wide the pulse width of the bit line section signal CSL is increased, data cannot be written. In the previous generation, the size of the transistor of a DQ gate was about 2 μm, with which data cannot be written. Here, at least, a width of 3 μm or more is necessary. In order to achieve a stable writing speed, a transistor size of about 4 μm to 5 μm is necessary.

In a memory have such a structure that data are read and written at the same time by multi-bit, such as a combined memory in which a memory circuit and a logic circuit are combined, a great number of columns are connected to a bit line selection signal line CSL, which is usually one line. When a great number of columns are connected to one bit line selection signal line CSL, the wiring capacitance is increased naturally. Therefore, the rising or falling speed of the bit line section signal CSL slows down, which causes flattening of the pulse of the signal CSL. Further, a skew occurs between a portion of the signal CSL that is closer to the driver and another portion that is far from the drive. These drawbacks are considered to be possible factors for interfering with a high speed operation of the device. Further, in such a case as described above where the size of the transistor that forms the DQ gate needs to be enlarged, these possible factors make the situation even worse, and therefore the high speed operation will be extremely difficult.

In the meantime, as a conventional technique to the present invention, there has been proposed a semiconductor memory device having the following structure. That is, a main column selection portion containing a driver is connected to one end of a column selection line CSL, and a latch circuit that serves to drive a column selection line CSL upon reception of an output signal from the driver is connected to the other end. (See Jpn. Pat. Appln. KOKAI Publication No. 2000-123571.)

### BRIEF SUMMARY OF THE INVENTION

According to an aspect of the present invention, there is provided a semiconductor memory device comprising: a memory cell array including a plurality of memory cells arranged in matrix; a plurality of bit line pairs to transmit or receive data with the plurality of memory cells; a plurality of sense amplifier circuits connected to the plurality of bit line pairs, respectively, to amplify data transferred to the respective bit line pairs; a plurality of data line pairs to transmit or receive data with the plurality of bit line pairs; a plurality of selection circuits each arranged between a respective bit line pair and a respective data line pair, to set one of a connection status and a disconnection status between the respective bit line pair and respective data line pair in accordance with a bit line selection signal; a sense amplifier bank which contains a plurality of those sense amplifier circuits, data line pairs and selection circuits; a control circuit to control the bit line selection signal supplied to a respective one of the plurality of selection circuits; a global bit line selection signal line connected to the control circuit, to receive the bit line section signal therefrom; a plurality of drive circuit, input portions of which are connected to the global bit line selection signal line, to drive the bit line selection signal supplied to the bit line selection signal line and output it, the plurality of drive circuits being arranged within the sense amplifier bank; and a local bit line selection signal line connected to output portions of the plurality of drive circuits, to supply the bit line selection signal driven by a respective one of the plurality of drive circuits, to the respective one of the plurality of selection circuits.

According to another aspect of the present invention, there is provided a semiconductor memory device comprising: a memory cell array including a plurality of memory cells arranged in matrix; a plurality of bit line pairs to transmit or receive data with the plurality of memory cells; a plurality of sense amplifier circuits connected to the plurality of bit line pairs, respectively, to amplify data transferred to the respective bit line pairs; a common source line to supply a first voltage to the plurality of sense amplifier circuits; and a sense amplifier driver to drive the common source line; wherein each of the plurality of sense amplifier circuits includes a first MOS transistor and a second MOS transistor which are connected to each other by cross-coupling, a gate of the sense amplifier driver is arranged to normally cross with an extending direction of the plurality of bit line pairs, and a connection portion of the sense amplifier drive to the common source line is located on a distant side from a region where the first MOS transistor and the second MOS transistor are arranged and a connection portion of the sense amplifier driver to a power supply wiring is located on a close side to the region.

### BRIEF DESCRIPTION OF THE SEVERAL VIEWS OF THE DRAWING

FIG. 1 is a circuit diagram showing an example of the structure of a sense amplifier in a conventional semiconductor memory device;

FIG. 2 is a timing chart illustrating an operation of the conventional memory device;

FIG. 3 is a circuit diagram showing an operation of the conventional semiconductor memory device in the case where circuits located on an outer side with respect to a data line pair are operated at a power supply voltage VDD, and the sense amplifier is operated at a voltage VBLH which is higher than voltage VDD;

FIG. 4 is a diagram indicating the writing speed of the case where a bit line selection signal CSL is driven at a voltage lower than that used for the sense amplifier in the semiconductor memory device;

FIG. 5 is a block diagram showing a layout of a main portion of a semiconductor memory device according to a first embodiment of the present invention;

FIG. 6 is a diagram showing a main structure of each of a sense amplifier bank and a sense amplifier control circuit in the semiconductor memory device according to the first embodiment;

FIG. 7 is a diagram showing a case where a plurality of systems (4 systems) of bit line selection signal lines are arranged in the sense amplifier bank in the semiconductor memory device according to the first embodiment;

FIG. 8 is a block diagram showing an example of the structure of each of a sense amplifier bank and a sense amplifier control circuit according to the conventional semiconductor memory device;

FIG. 9A is a block diagram showing a layout of a main portion of a semiconductor memory device according to a second embodiment of the present invention, and FIG. 9B is a cross sectional view of a word line stitch region in FIG. 9A taken along a direction of a word line;

FIG. 10 is a schematic diagram showing a structure of a semiconductor memory device which employs a segmented word line mode, according to a remodeled version of the second embodiment of the present invention;

FIG. 11 is a block diagram showing a layout of a main portion of a semiconductor memory device according to a third embodiment of the present invention;

FIG. 12 is a block diagram showing a layout of a sense amplifier region and re-driver region of a semiconductor memory device according to a fourth embodiment of the present invention;

FIG. 13 is a block diagram showing a main structure of a sense amplifier bank in a semiconductor memory device according to a fifth embodiment of the present invention;

FIG. 14 is a diagram showing an example of a faulty occurred in the sense amplifier bank of the semiconductor memory device according to the fifth embodiment;

FIG. 15 is a diagram showing an example of a transistor leak error occurred in the re-driver of the sense amplifier bank of the semiconductor memory device according to the fifth embodiment;

FIG. 16 is a diagram showing a main structure of a sense amplifier bank in a semiconductor memory device according to a remodeled version of the fifth embodiment of the present invention;

FIG. 17 is a diagram showing a normal column block and a redundancy column block in the semiconductor memory device according to the fifth embodiment;

FIG. 18 is a block diagram showing a layout of a sense amplifier region and re-driver region of a semiconductor memory device according to a sixth embodiment of the present invention; and

FIG. 19 is a block diagram showing a main structure of a sense amplifier bank in a semiconductor memory device according to a seventh embodiment of the present invention.

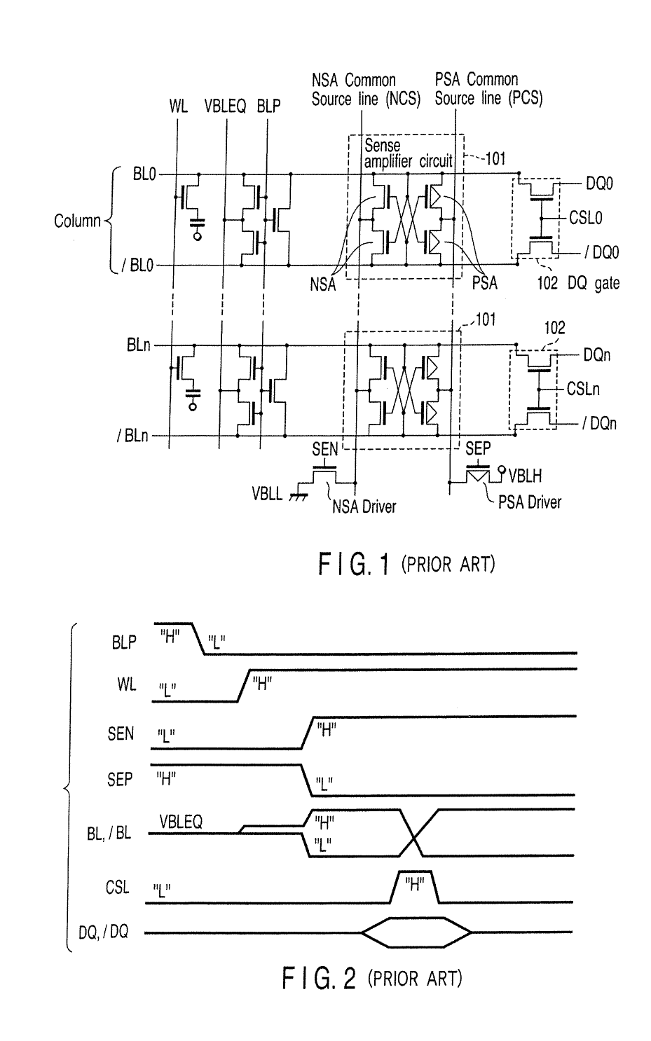

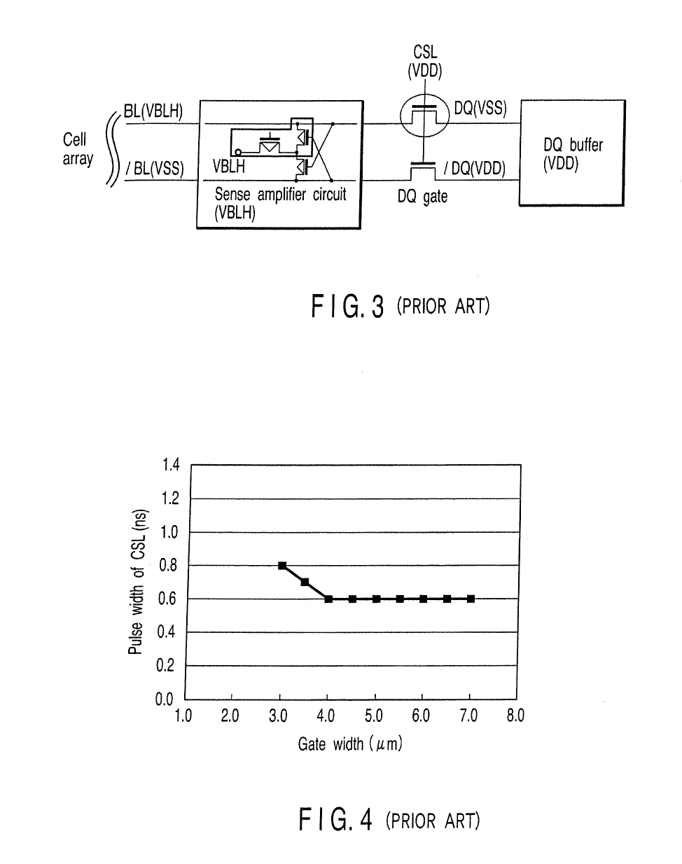

### DETAILED DESCRIPTION OF THE INVENTION

Embodiments of the present invention will now be described with reference to accompanying drawings. Throughout the drawings, common structural parts will be designated by common reference symbols in the following descriptions.

### First Embodiment

First, a semiconductor memory device according to the first embodiment of the present invention will now be described.

In the first embodiment, a plurality of re-drivers are provided in a sense amplifier bank, and each re-driver serves to re-drive a bit line selection signal CSL driven in a sense amplifier control circuit.

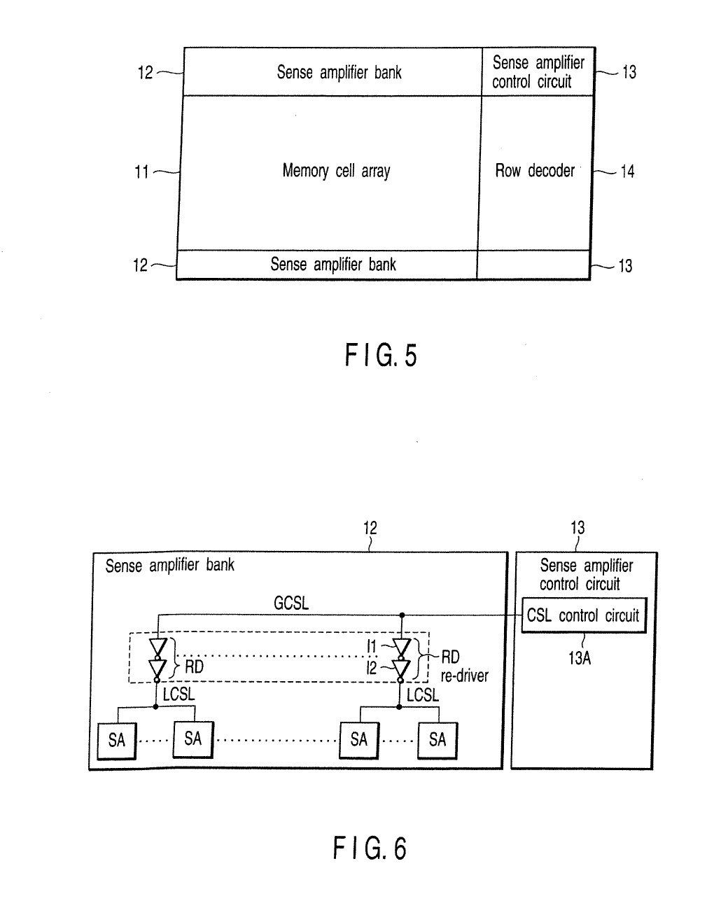

FIG. 5 is a block diagram showing a layout of the main portion of the semiconductor memory device according to the first embodiment.

As shown in FIG. 5, the semiconductor memory device includes a memory cell array 11, a sense amplifier bank 12, a sense amplifier control circuit 13 and a row decoder 14. The memory cell array 11 includes a plurality of memory cells arranged in matrix. Along the memory cell array 11, the sense amplifier bank 12 is arranged to be adjacent to the memory cell array 11 in its column direction. The row decoder 14 is arranged to be adjacent to the memory cell array 11 along its row direction. The row decoder 14 selects a word line connected to a memory cell based on an address signal and drives the selected word line. Further, along the sense amplifier bank 12, the sense amplifier control circuit 13 is arranged to be adjacent to the sense amplifier bank 12 in its row direction.

FIG. 6 shows a main structure of each of the sense amplifier bank 12 and sense amplifier control circuit 13 shown in FIG. 5. The sense amplifier bank 12 includes a sense amplifier SA and a re-driver RD. The sense amplifier SA includes a sense amplifier circuit 101, a DQ gate 102 and data line pairs DQn,/DQn (n=0, 1, 2, . . . , n). The sense amplifier circuit 101 includes cross-coupled two N channel MOS transistors (NSA) and cross-coupled two P channel MOS transistors (PSA). The DQ gate includes two N channel MOS transistors connected between a bit line pair BLn,/BLn and a data line pair DQn,/DQn. A bit line selection signal CSLn is supplied to the gate of a respective one of the N channel MOS transistors, and the respective N channel MOS transistor sets connection or disconnection between the respective bit line pair BLn,/BLn and data line pair DQn,/DQn in accordance with the respective bit line selection signal CSLn. Further, the re-driver RD includes, for example, two inverters I1 and I2, and it drives a bit line selection signal at a location close to the sense amplifier SA.

The sense amplifier control circuit 13 includes a bit line selection signal control circuit (to be referred to as CSL control circuit hereinafter) 13A which controls bit line selection signals. Global bit line selection signal lines (to be referred to as GCSL lines hereinafter) are connected to the CSL control circuit 13A, and global bit line selection signals GCSL (to be referred to as signals GCSL hereinafter) are outputted to the GCSL lines from the CSL control circuit 13A. The GCSL lines are connected to input portions of a plurality of re-drivers RD, respectively, and output portions of the re-drivers RD are connected to a plurality of sense amplifiers SA, respectively. In other words, the re-drivers RD, provided for every several columns, are connection in parallel to the GCSL lines, and local bit line selection signal lines (to be referred to as LCSL lines hereinafter) are connected to the re-drivers RD, respectively. Further, the LCSL lines are connected respectively to DQ gates of a plurality of sense amplifiers SA.

A signal GCSL driven by the CSL control circuit 13A and then supplied to the respective GCSL line is re-driven by the respective re-driver RD, and then output as a local bit line selection signal (to be referred to as signal LCSL hereinafter) to the respective LCSL line. The signal LCSL output to the LCSL line is supplied to the DQ gate in the sense amplifier SA connected to that LCSL line. In this manner, the DQ gates of the sense amplifiers SA in the sense amplifier bank 12 are activated by signals LCSL supplied from the CSL control circuit 13A and driven by the re-drivers RD.

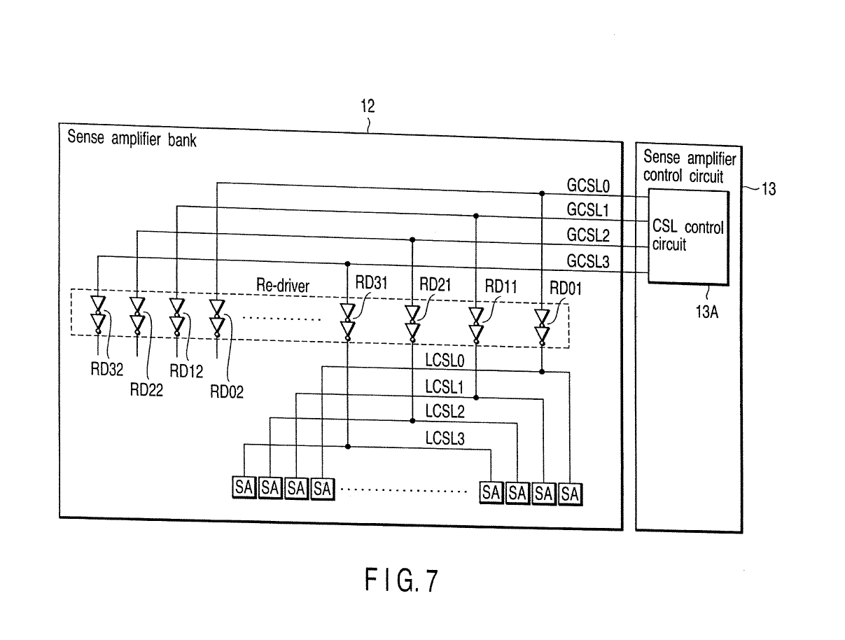

FIG. 7 is a diagram showing a case where a plurality of systems (4 systems) of bit line selection signal lines are arranged in the sense amplifier bank 12. For example, in the case where one sense amplifier bank includes 512 columns and there are 4 systems of bit line selection signals CSL, the number of columns connected to one system of bit line selection signal CSL is 128. A plurality of re-drivers are connected to each of the four systems of global bit line selection signal lines (line GCSL0 to line GCSL3). Local bit line selection signal lines (line LCSL0 to line LCSL3) are connected to output portions of the re-drivers, respectively, and LCSL0 line to LCSL3 line are connected to the DQ gates of the sense amplifiers SA, respectively.

In more detail, 4 systems of GCSL0 line to GCSL3 are connected to the CSL control circuit 13A. The GCSL0 line is connected to the re-drivers RD01 and RD02, and the LCSL0 line is connected to the re-driver RD01. Further, a plurality of sense amplifiers SA are connected to the LCSL0 line. Although not shown in the figure, LCSL lines are connected to the re-driver RD02, and a plurality of sense amplifiers are connected to the LCSL lines. Meanwhile, the GCSL1 line is connected to the re-drivers RD11 and RD12, and the LCSL1 line is connected to the re-driver RD11. Further, a plurality of sense amplifiers SA are connected to the LCSL1 line. Although not shown in the figure, LCSL lines are connected to the re-driver RD12, and a plurality of sense amplifiers are connected to the LCSL lines. Similarly, the GCSL2 line is connected to the re-drivers RD21 and RD22, and the LCSL2 line is connected to the re-driver RD21. Further, a plurality of sense amplifiers SA are connected to the LCSL2 line. Although not shown in the figure, LCSL lines are connected to the re-driver RD22, and a plurality of sense amplifiers are connected to the LCSL lines. Similarly, the GCSL3 line is connected to the re-drivers RD31 and RD32, and the LCSL3 line is connected to the re-driver RD31. Further, a plurality of sense amplifiers SA are connected to the LCSL3 line. Although not shown in the figure, LCSL lines are connected to the re-driver RD32, and a plurality of sense amplifiers are connected to the LCSL lines.

In FIG. 7, the LCSL0 line to LCSL3 line are connected in this order to sense amplifiers SA arranged successively; however it is also possible that those sense amplifiers connected to LCSL lines of the same system are arranged consecutively.

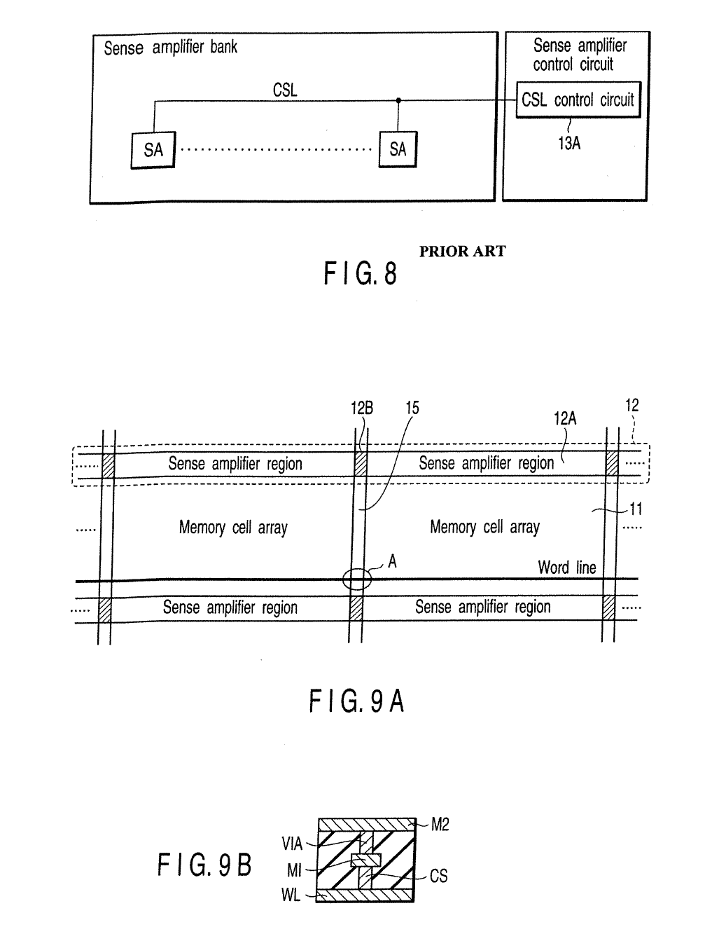

FIG. 8 shows a prior art example, in which the DQ gates of all the sense amplifiers SA in a sense amplifier bank are connected directly to bit line selection signal lines CSL connected to the CSL control circuit 13A. As compared to this prior art example, the first embodiment of the present invention has a smaller wiring capacity of the GCSL lines. Therefore, it is possible to prevent the flattening of the pulse of a signal GCSL, which is caused by a fall of the rising or falling speed of the bit line selection signal GCSL supplied to the GCSL line. Further, the bit line section signal LCSL which is generated by re-driving a signal GCSL and supplied to an LCSL line becomes a stable pulse signal. Furthermore, a skew of a bit line selection signal that occurs between a portion of the signal CSL that is closer to the CSL control circuit and another portion that is far from the circuit can be made small, thereby achieving a structure suitable for a high speed operation. As discussed above in connection with the background art, this advantage is particularly significant in the case where the size of DQ gate needs to be enlarged.

### Second Embodiment

Next, a semiconductor memory device according to the second embodiment of the present invention will now be described. In this embodiment, similar structural parts to those of the first embodiment will be designated by the reference symbols, and explanations for these parts will be omitted. The followings are descriptions of the parts different from those of the first embodiment.

In the second embodiment, a re-driver serving to re-drive a bit line selection signal CSL is provided in each of empty regions created in a sense amplifier bank adjacent to word line stitch regions.

FIG. 9A is a block diagram showing a layout of the main portion of a semiconductor memory device according to the second embodiment of the present invention.

As shown in FIG. 9A, the semiconductor memory device includes memory cell arrays 11, sense amplifier banks 12 and word line stitch regions 15. Each of the memory cell arrays 11 includes a plurality of memory cells arranged in matrix. Along the memory cell arrays 11, the sense amplifier bank 12 is arranged to be adjacent to each of the memory cell array 11 in its column direction. Each of the sense amplifier bank 12 includes a plurality of sense amplifier regions 12A each provided for a respective memory cell array 11, and each of the sense amplifier regions 12A includes a plurality of sense amplifiers. Each of the word line stitch regions 15 is arranged between the respective memory cell arrays 11 arranged to be adjacent in its row direction.

In the case where an empty region 12B exists between adjacent sense amplifier regions 12A in a sense amplifier bank 12 in a semiconductor memory device having such a structure as described above, a re-driver is provided in the empty region 12B. In other words, in the case where there is an empty region 12B in an area in a sense amplifier bank, that is adjacent to a word line stitch region 15, a re-driver is provided in the empty region 12B in the second embodiment. With this arrangement, it is possible to avoid an increase in the area of each of the sense amplifier banks 12 due to arrangement of the re-driver.

FIG. 9B is a cross sectional view of part A in FIG. 9A, which is a word line stitch region 15 taken along a direction of a word line. A low-resistance metal wiring M2 is provided above a word line (GC wiring) WL. A contact member CS, a metal wiring M1 and a contact member VIA are formed between the word line WL and the low-resistance metal wiring M2, and the word line WL and the low-resistance metal wiring M2 are electrically connected to each other. As described, each of the world lines WL is connected to the low-resistance metal wiring M2 corresponding to the respective word line WL in a respective word line stitch region 15. In other words, each word line stitch region 15 is a region to connect (stitch) a word line WL and a respective low-resistance metal wiring M2 arranged in parallel with the word line WL to each other. With this structure, the signal delay of each word line WL can be suppressed.

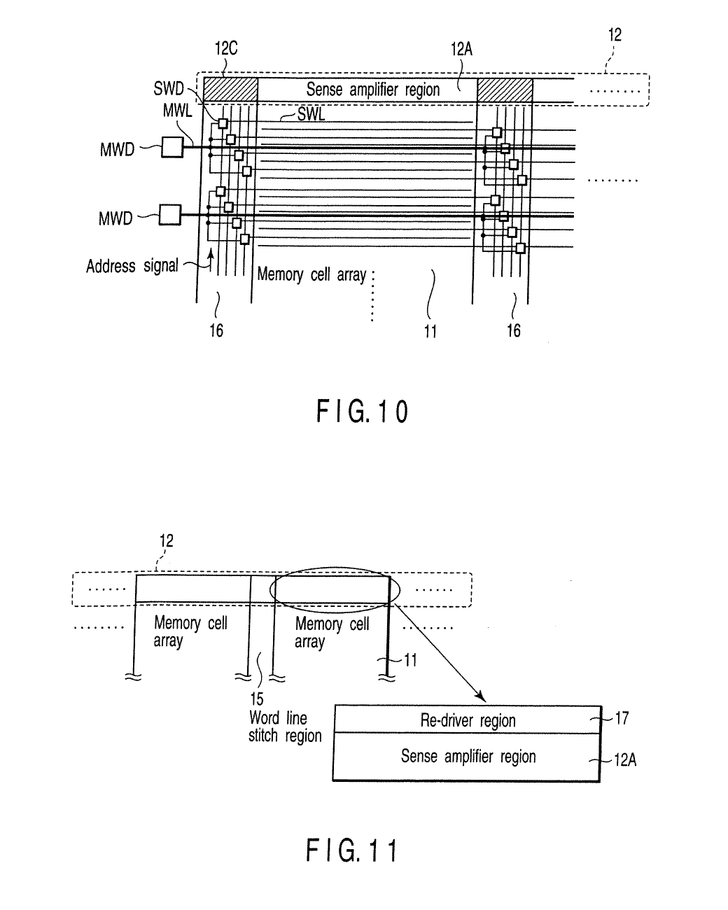

FIG. 10 is a schematic diagram showing a structure of a semiconductor memory device which employs a segmented word line system.

As shown in FIG. 10, this semiconductor memory device includes memory cell arrays 11, sense amplifier banks 12 and sub-word line driver regions 16. Along the memory cell arrays 11, the sense amplifier bank 12 is arranged to be adjacent to each of the memory cell array 11 in its column direction. Each of the sense amplifier bank 12 includes a plurality of sense amplifier regions 12A each provided for a respective memory cell array 11, and each of the sense amplifier regions 12A includes a plurality of sense amplifiers. Along the memory cell arrays 11, the sub-word line driver regions 16 are arranged to be adjacent to the memory cell arrays 11 respectively in their row direction. There is an empty region 12C created in a region at each cross section between the sense amplifier banks 12 and the sub-word line driver regions 16.

In each of the memory cell arrays 11, a plurality of main word lines MWL are provided. Each of the main word lines MWL is connected to a main word line driver MWD serving to drive the respective main word line MWL. Each of the main word line MWL is connected to, for example, 4 sub-word lines SWL via sub-word line drivers SWD. An address signal is supplied to each of the sub-word line driver SWD, and each sub-word line driver SWD serves to drive the sub-word line SWL based on the address signal. It should be noted that the sub-word line driver SWD is provided in the respective sub-word line driver region 16. Each sub-word line driver region 16 is provided for every predetermined number of columns.

In the case of the layout shown in FIG. 10, where the sub-word line drivers 16 are provided, empty regions 12C are created between sense amplifier regions 12A in each sense amplifier bank 12. Therefore, in the semiconductor memory device shown in FIG. 10, by arranging the re-drivers in the empty regions 12C, an increase in the area of each sense amplifier bank 12 due to arrangement of the re-driver can be prevented. It should be noted that the other advantages of the second embodiment that can be obtained by providing the re-drivers are similar to those of the first embodiment.

### Third Embodiment

Next, a semiconductor memory device according to the third embodiment of the present invention will now be described. In this embodiment, similar structural parts to those of the first embodiment will be designated by the reference symbols, and explanations for these parts will be omitted. The followings are descriptions of the parts different from those of the first embodiment.

In the third embodiment, a re-driver serving to re-drive a bit line selection signal CSL is provided in a region adjacent to a sense amplifier region in which sense amplifiers are repeatedly arranged.

FIG. 11 is a block diagram showing a layout of the main portion of a semiconductor memory device according to the third embodiment of the present invention.

As shown in FIG. 11, this semiconductor memory device includes memory cell arrays 11, sense amplifier banks 12, word line stitch regions 15 and re-driver regions 17, Along the memory cell arrays 11, the sense amplifier bank 12 is arranged to be adjacent to each of the memory cell array 11 in its column direction. Each of the sense amplifier bank 12 includes a plurality of sense amplifier regions 12A each provided for a respective memory cell array 11, and each of the sense amplifier regions 12A includes a plurality of sense amplifiers. A word line stitch region 15 is provided between memory cell arrays 11 arranged to be adjacent to each other in their row direction. A re-driver region 17 is formed to be adjacent to a respective sense amplifier region 12A, and each re-driver region includes a plurality of re-drivers arranged therein. Each re-driver region 17 is provided in a region that opposes a respective memory cell array 11 via a respective sense amplifier region 12A.

Here, let us suppose, for example, a case where there is one system of bit line selection signal line CSL. In this case, when a re-driver is provided in each region 12B adjacent to a respective word line stitch region 15 as in the second embodiment, all of sense amplifiers located in a sense amplifier bank are categorized for each word line stitch region, and the categorized sense amplifiers are connected by group to the LCSL line connected to the re-drivers arranged for each word line stitch region. With this structure, there is a number of sense amplifiers connected to the LCSL line and therefore the wiring capacity of the LCSL line becomes very large. Therefore, the size of the re-drivers should necessarily be increased to a certain level. However, when there is no such a large space assigned to the region 12B adjacent to the respective word line stitch region 15, it is naturally not possible to provide re-drivers of a sufficient size. As a result, the rising and falling speeds of the bit line selection signal LCSL supplied to the LCSL line falls. Supposing a case where there are 4 systems of bit line selection signals CSL, the number of sense amplifiers connected to each LCSL line is ¼ of that of the case where there is one system. However, even under that condition, the wiring capacitance of each LCSL line is not always made sufficiently small, but re-drivers for the 4 systems still need to be provided in the each word line stitch region. Thus, the circumstance where re-drivers of a sufficient size cannot be provided cannot be improved very much.

Under these circumstances, in the third embodiment, a re-driver is provided in a region adjacent to the sense amplifier region 12A in which sense amplifiers are repeatedly provided. With this structure, it becomes possible to form re-drivers of a sufficient size and increase the degree of freedom in the number of re-drivers provided, thereby allowing flexible designing of sense amplifiers. If an increment of the area caused by newly providing a region where re-drivers are provided is within an allowable range, the third embodiment is very effective measures to realize a high speed operation. It should be noted that the other advantages of the third embodiment that can be obtained by providing the re-drivers are similar to those of the first embodiment.

### Fourth Embodiment

Next, a semiconductor memory device according to the fourth embodiment of the present invention will now be described. In this embodiment, similar structural parts to those of the first embodiment will be designated by the reference symbols, and explanations for these parts will be omitted. The followings are descriptions of the parts different from those of the first embodiment.

In the fourth embodiment, an active region for use of well contact, which serves to supply a well potential to a transistor of a sense amplifier, is not provided in a sense amplifier region in which sense amplifiers are repeatedly provided, but in place, the well contact-use active region is provided in a re-driver region where a plurality of re-drivers are arranged. That is, the well potential of the transistor included in a sense amplifier is supplied via the well contact-use active region arranged in the re-driver region in which a plurality of re-drivers are provided.

In order to form a well contact-use active region in a sense amplifier region in which a plurality of sense amplifiers are repeatedly provided, such a region must be created. On the other hand, the re-driver region provided adjacent to the sense amplifier region has an empty section, and therefore the well contact-use active region is formed in the empty section. The well potential of the sense amplifier is supplied via the well contact-use active region provided in the re-driver region. With this structure, the area of the well contact-use active region is reduced in the sense amplifier region, and thus the area of the sense amplifier bank including the sense amplifier region can be suppressed to a minimum.

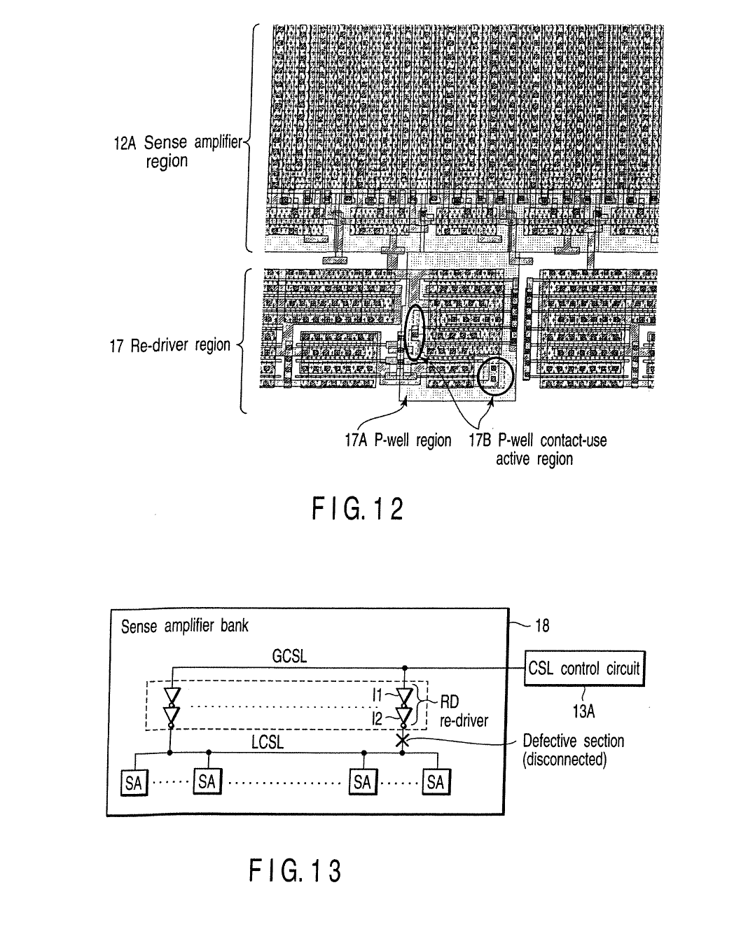

FIG. 12 is a block diagram showing a layout of the sense amplifier region 12A and re-driver region 17 of a semiconductor memory device according to the fourth embodiment of the present invention. FIG. 12 illustrates an example case where the P well potential of an N channel MOS transistor included in the sense amplifier region 12A is supplied via a P well contact-use active region 17B arranged in a P well region 17A within the re-driver region 17. Or in the case where a P channel MOS transistor is provided adjacent to the re-driver region, it suffices if the N well potential of the P channel MOS transistor is supplied via an N well contact-use active region provided in the re-driver region. With this arrangement, it is not necessary to form a well contact-use active region in the sense amplifier region, and therefore the area of the sense amplifier bank including the sense amplifier region can be suppressed to a minimum.

FIG. 12 illustrates a case where the re-drivers are arranged in the re-driver region 17 adjacent to the sense amplifier region 12A in which sense amplifiers are repeatedly arranged. For example, as described in connection with the second embodiment, in the case where the re-drivers are formed in the empty region 12B in the sense amplifier bank 12 adjacent to the word line stitch region 15, or the case of the segmented word line system, the area of the sense amplifier bank can be suppressed to a minimum. That is, even in the case where the re-drivers are formed in the empty region 12C in the sense amplifier bank adjacent to the sub-word line driver region 16, it suffices if the well contact-use active region is provided in the regions 12B and 12C where the re-drivers are provided, to reduce the area to a minimum. It should be noted that the other advantages of the second embodiment that can be obtained by providing the re-drivers are similar to those of the first embodiment.

### Fifth Embodiment

Next, a semiconductor memory device according to the fifth embodiment of the present invention will now be described. In this embodiment, similar structural parts to those of the first embodiment will be designated by the reference symbols, and explanations for these parts will be omitted. The followings are descriptions of the parts different from those of the first embodiment.

In the fifth embodiment, LCSL lines each connected to output portions of a plurality of re-drivers are connected to each other in a sense amplifier bank.

FIG. 13 is a block diagram showing the main structure of a sense amplifier bank 18 in a semiconductor memory device according to the fifth embodiment of the present invention. As shown, a GCSL line is connected to a CSL control circuit 13A, and a bit line selection signal GCSL is output to the GCSL line from the CSL control circuit 13A. The GCSL line is connected to input portions of a plurality of re-drivers RD, and output portions of the re-drivers RD are connected to an LCSL line. Further, the LCSL line is connected to a plurality of sense amplifiers SA. In other words, the re-drivers RD each provided for every several columns are connection in parallel to the GCSL line, and each of the re-drivers is connected to the same LCSL line. Further, the LCSL line is connected to DQ gates of the plurality of sense amplifiers SA.

In a sense amplifier bank 18 having the above-described structure, even if, for example, the output portion of a re-driver RD is disconnected from the LCSL line as shown in FIG. 13, it is possible to prevent the LCSL line from becoming completely non-functional since other re-drivers are connected to the LCSL line.

Next, a semiconductor memory device according to a remodeled version of the fifth embodiment will now be described.

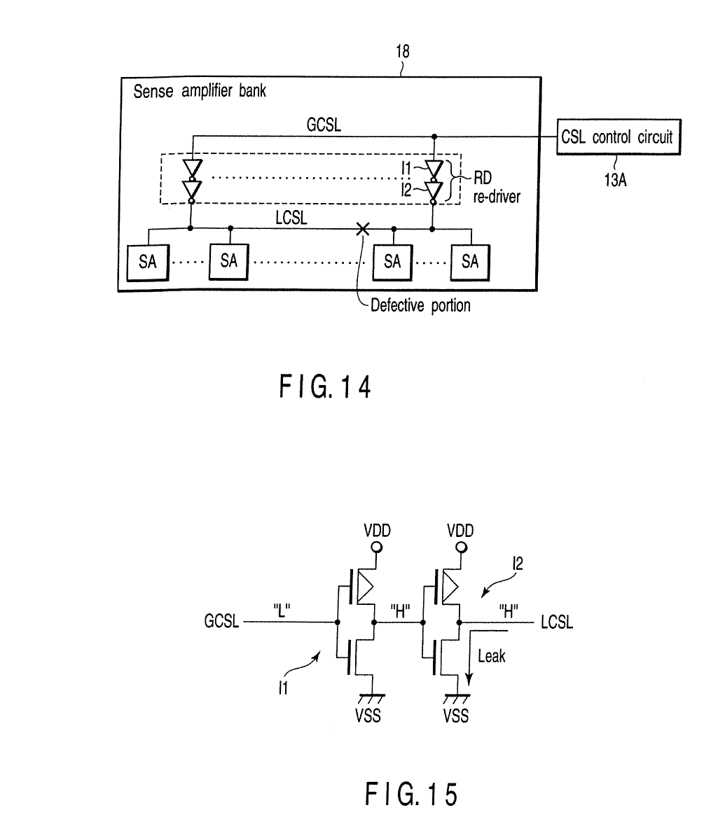

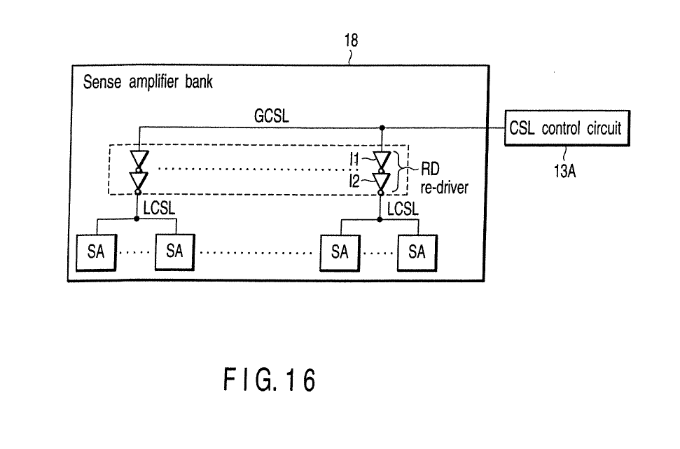

On the other hand, the fifth embodiment entails the following shortcomings. That is, in the case where a defect such as large leak occurs somewhere in the LCSL line as shown in FIG. 14, there is a possibility that all of the columns connected to the line are affected by the defect. Or, if the operation of signal LCSL becomes faster than that of signal GCSL, in a re-driver portion where the operation of the signal LCSL is faster, the output operation becomes faster than the input operation, causing transistor leak. FIG. 15 is a diagram showing an example of transistor leak occurred in the case where the rising of the signal LCSL occurs earlier than the rising of the signal GCSL. In this remodeled example, LCSL lines connected to the re-drivers each provided for every several columns are not connected to each other as can bee seen in FIG. 16. With this arrangement, the above-described drawback can be avoided.

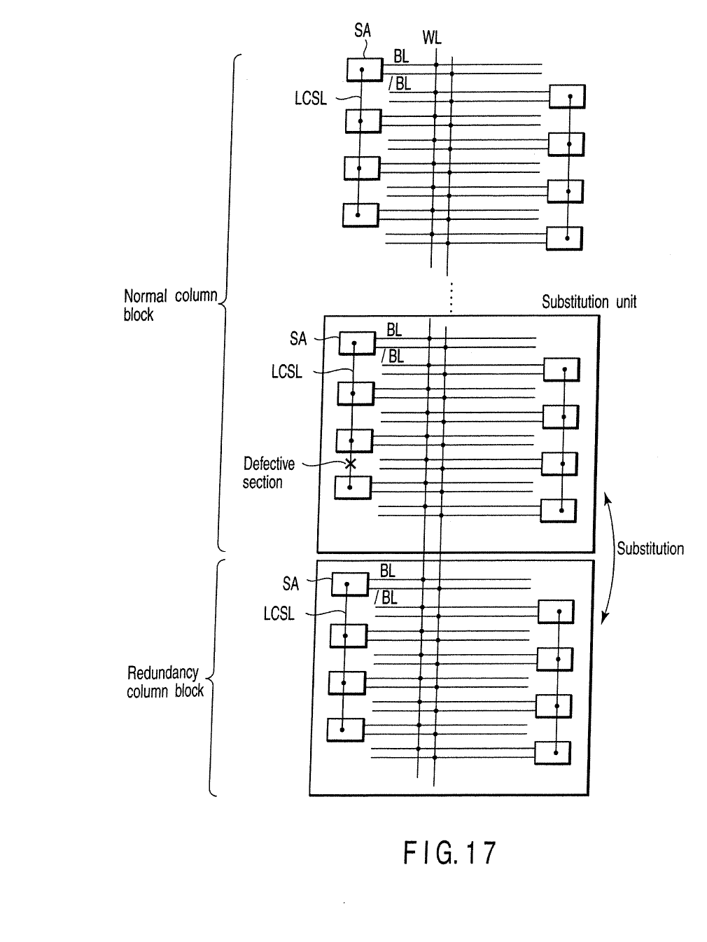

FIG. 17 is a diagram showing a normal column block and a redundancy column block in the semiconductor memory device according to the fifth embodiment. A normal column block includes a plurality of normal columns and a redundancy column block includes a plurality of redundancy columns. A redundancy column is used as a substitute for a normal column when it becomes defective. As shown in FIG. 17, in a normal column block, a plurality of sense amplifiers SA are connected to an LCSL line, and a bit line pair BL,/BL is connected to each sense amplifier SA. Similarly, in a redundancy column block, a plurality of sense amplifiers SA are connected to an LCSL line, and a bit line pair BL,/BL is connected to each sense amplifier SA.

Here, this remodeled version provides such a structure that sense amplifiers (column) connected to an LCSL line in a normal column are included in a replacement unit of a redundancy column, that is, in other words, a plurality of sense amplifiers (including DQ gates) connected to the same LCSL line are arranged within a substitution unit of redundancy column. With this structure, if an error caused by a defective LCSL line occurs, such an error can be relieved. It should be noted that FIG. 17 illustrates the case where the number of columns connected to an LCSL line is the same as the number of columns connected to an LCSL line included in a substitution unit of redundancy column.

### Sixth Embodiment

Next, a semiconductor memory device according to the sixth embodiment of the present invention will now be described. In this embodiment, similar structural parts to those of the first embodiment will be designated by the reference symbols, and explanations for these parts will be omitted. The followings are descriptions of the parts different from those of the first embodiment.

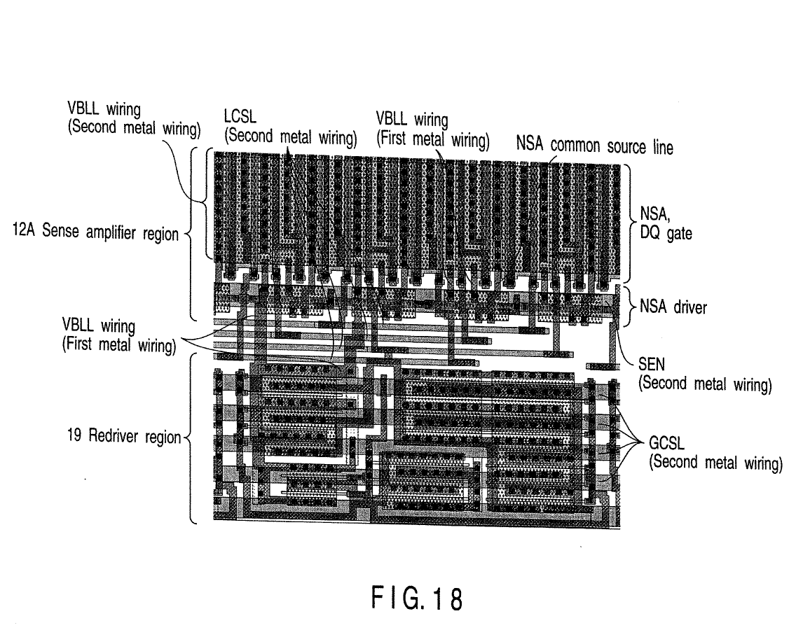

FIG. 18 is a block diagram showing a layout of a sense amplifier region and re-driver region of a semiconductor memory device according to the sixth embodiment of the present invention.

In a re-driver region 19 where re-drivers are provided, global bit line selection signal lines (GCSL lines) are formed of the second metal wiring (M2). In the sixth embodiment, there are 4 systems of GCSL lines, which are made of the second metal wirings, and therefore it is difficult to make power supply lines for re-drivers using the second metal wiring. Under these circumstances, in the sixth embodiment, the ground potential (, which is equal to VBLL,) of a re-driver is supplied by connecting a VBLL wiring to which the voltage VBLL in the sense amplifier region 12A and a first metal wiring (M1) to each other.

Further, the layout shown in FIG. 18 has the following characteristics.

In a region above where an NSA driver is provided, a signal line SEN is made of the second metal wiring in its gate direction. The NSA driver is a transistor serving to drive an N channel MOS transistor (NSA) included in a sense amplifier circuit. A drain of the NSA driver is connected to a common source line node. A sense amplifier activation signal SEN is supplied to a gate of the NSA driver, and a low level bit line voltage VBLL is supplied to a source of the NSA driver. The NSA driver serves to drive the NSA by supplying the voltage VBLL to the NSA via the NSA common source line. In order to achieve a stable sensing operation, the wiring for the power VBLL is made of a thick second metal wiring and provided in a region above where the N channel MOS transistor (NSA) and DQ gate included in a sense amplifier circuit are provided. Further, the common source line node of the NSA driver is arranged on a side (lower side) that is distant from the NSA and the DQ gate, and a VBLL wiring node is arranged on a side (upper side) that is close to the NSA and DQ gate. With this arrangement, the VBLL wiring made of the first metal wiring and the second metal wiring can be easily connected to each other.

### Seventh Embodiment

Next, a semiconductor memory device according to the seventh embodiment of the present invention will now be described. In this embodiment, similar structural parts to those of the first embodiment will be designated by the reference symbols, and explanations for these parts will be omitted. The followings are descriptions of the parts different from those of the first embodiment.

In the case where, for example, one redundancy column is provided for every several normal columns, there is such a problem arises regarding the size of re-drivers serving to supply a bit line selection signal to a column group that includes the redundancy column.

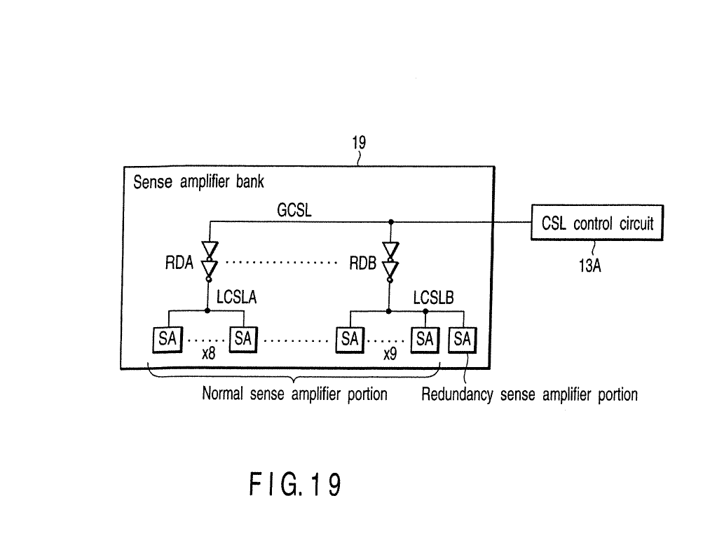

FIG. 19 is a block diagram showing the main structure of a sense amplifier bank 19 in a semiconductor memory device according to the seventh embodiment of the present invention. A GCSL line is connected to a CSL control circuit 13A, and a bit line selection signal GCSL is output from the CSL control circuit 13A to the GCSL line. The GCSL line is connected to an input portion of each of re-drivers RDA and RDB. An output portion of the re-driver RDA is connected to an LCSLA line, and an output portion of the re-driver RDB is connected to an LCSLB line. A plurality of normal sense amplifiers SA are connected to the LCSLA line, and a plurality of normal sense amplifiers SA and a redundancy sense amplifier SA are connected to the LCSLB line.

As shown in FIG. 19, for example, 8 sense amplifiers SA are connected to an LCSLA line corresponding to a region that includes a normal column only, and 9 sense amplifiers SA including one for a redundancy column are connected to an LCSLB line corresponding to a region that includes the redundancy column. In this case, if the size (that is, the gate width of the transistor) of the re-driver RDA is set equal to that of the re-driver RDB, there is a possibility that the rising and falling speeds of the signal LCSLB supplied to the LCSLB line becomes slower than those of the signal LCSLA supplied to the LCSLA line.

In order to avoid this, the size of re-drivers is determined in accordance with the number of sense amplifiers connected to the re-drivers in the seventh embodiment. In the sense amplifier bank 19 shown in FIG. 19, the size of the re-driver RDB is set to about 9/8 times as the size of the re-driver RDA. With this arrangement, the rising and falling speeds of the signal LCSLA can be made substantially equal to those of the signal LCSLB. It should be noted that the other advantages of the seventh embodiment that can be obtained by providing the re-drivers are similar to those of the first embodiment.

### Eighth Embodiment

Next, a semiconductor memory device according to the eighth embodiment of the present invention will now be described. In this embodiment, similar structural parts to those of the first embodiment will be designated by the reference symbols, and explanations for these parts will be omitted. The followings are descriptions of the parts different from those of the first embodiment.

A semiconductor memory device in which different types of transistors are used depending on voltages at which these transistors are operated will now be described. For example, the transistors operated at a low voltage are characterized by their thin gate oxide film, short gate length, etc., which are designed so to as to realize a high-speed operation.

In a sense amplifier shown in FIG. 1, a bit line precharge transistor driven at a voltage VPP, which is an “H” level potential of the word line, is made of a transistor with a thick oxide film (that is, thick film transistor). The other types of transistors, which are driven at a voltage VBLH which is an “H” level potential of the bit line, are made of transistors with an oxide film thinner than the above-mentioned thick oxide film (that is, medium-thickness film transistor). In the case where the power supply voltage of the peripheral logic portion is lower than the high-level bit line potential VBLH, the peripheral logic portion is made of transistors with a further thinner oxide film (that is, thin film transistors).

As described above, in the case where the bit line selection signal CSL is driven at the power supply voltage VDD, which is the same as that of the peripheral logic portion, a thin film transistor as well can be used for a re-driver. In the case where transistors with oxide films of different thicknesses are mixedly present in a semiconductor memory device, a large space is required between transistors in order to form oxide films of different thicknesses from each other. Therefore, if a re-driver made of a thin film transistor is provided in a sense amplifier which does not contain any thin film transistor, a large space is required, thereby increasing the area.

Here, let us consider the size of a transistor necessary for achieving a certain driving capability. A thin film transistor can achieve the required certain driving capability with a size smaller than that of a transistor with a thick oxide film, and therefore the area occupied by the transistor itself becomes smaller. Therefore, if the area reduction effect is larger than the increment in area due to the large space required to form the transistors of oxide films of various thicknesses, the increment in area caused by arranging the re-drivers in a certain way can be suppressed to a minimum level. Alternatively, if transistors having oxide film of the same thickness but having a threshold voltage lower than that of the transistor included in the sense amplifier and a current driving capability higher than that of the transistor are used for the re-drivers, the increment in area can be suppressed to a minimum level. It should be noted that the other advantages of the eighth embodiment that can be obtained by providing the re-drivers are similar to those of the first embodiment.

As described above, according to the embodiments of the present invention, it is possible to provide a semiconductor memory device that can surely supply a pulse of a bit line selection signal CSL to a DQ gate, and suppress skew of a bit line selection signal CSL in a sense amplifier bank, thereby making it possible to perform a high-speed reading and writing operation.

The above embodiments and modifications can be individually or in combination put to practical use. Furthermore, they contain a number of inventive aspects at different levels. Thus, a number of inventions at different levels can be extracted by properly selectively combining the structural elements disclosed above with respect to the embodiments and modifications.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor memory device comprising:
a memory cell array including a plurality of memory cells arranged in matrix;
a plurality of bit line pairs to transmit or receive data with the plurality of memory cells;
a plurality of sense amplifier circuits connected to the plurality of bit line pairs, respectively, to amplify data transferred to the respective bit line pairs;
a plurality of data line pairs to transmit or receive data with the plurality of bit line pairs;
a plurality of selection circuits each arranged between a respective bit line pair and a respective data line pair, to set one of a connection status and a disconnection status between the respective bit line pair and respective data line pair in accordance with a bit line selection signal;
a sense amplifier bank which contains a plurality of those of the plurality of sense amplifier circuits, data line pairs and selection circuits;
a control circuit to control the bit line selection signal supplied to a respective one of the plurality of selection circuits;
a global bit line selection signal line connected to the control circuit, to receive the bit line selection signal therefrom;
a plurality of drive circuit, input portions of which are connected to the global bit line selection signal line, to drive the bit line selection signal supplied to the global bit line selection signal line and output it, the plurality of drive circuits being arranged within the sense amplifier bank; and
a local bit line selection signal line connected to output portions of the plurality of drive circuits, to supply the bit line selection signal driven by a respective one of the plurality of drive circuits, to the respective one of the plurality of selection circuits;
wherein the sense amplifier bank includes a sense amplifier region in which sense amplifiers including the sense amplifier circuits and the selection circuits are repeatedly arranged, and
the plurality of drive circuits are arranged in a region which is in the sense amplifier bank and adjoined the sense amplifier region.

2. The semiconductor memory device according to claim 1, wherein the sense amplifier circuit includes an N channel MOS transistor and a P channel MOS transistor, a P well potential of the N channel MOS transistor is supplied via an active region for P well contact, provided in a region where the plurality of drive circuit are arranged.

3. The semiconductor memory device according to claim 1, wherein the sense amplifier circuit includes an N channel MOS transistor and a P channel MOS transistor, an N well potential of the P channel MOS transistor is supplied via an active region for N well contact, provided in a region where the plurality of drive circuit are arranged.

4. The semiconductor memory device according to claim 1, wherein the global bit line selection signal line is connected to input portions of the plurality of drive circuits, and each of output portions of the plurality of drive circuits is connected to the different selection circuit through the local bit line selection signal line.

5. The semiconductor memory device according to claim 1, wherein each of output portions of the plurality of drive circuits is connected to the plurality of selection circuits through the local bit line selection signal line, and the plurality of selection circuits connected to the same local bit line selection signal line are arranged within the same substitution unit of redundancy column, which can be substituted with a defective memory cell, arranged in the sense amplifier bank.

6. The semiconductor memory device according to claim 2, wherein each of output portions of the plurality of drive circuits is connected to the plurality of selection circuits through the local bit line selection signal line, and the plurality of selection circuits connected to the same local bit line selection signal line are arranged within the same substitution unit of redundancy column, which can be substituted with a defective memory cell, arranged in the sense amplifier bank.

7. The semiconductor memory device according to claim 3, wherein each of output portions of the plurality of drive circuits is connected to the plurality of selection circuits through the local bit line selection signal line, and the plurality of selection circuits connected to the same local bit line selection signal line are arranged within the same substitution unit of redundancy column, which can be substituted with a defective memory cell, arranged in the sense amplifier bank.

8. The semiconductor memory device according to claim 1, wherein a power supply is supplied to the plurality of drive circuits by connecting a power supply wiring and a first metal wiring to each other, which are formed in the sense amplifier region in which the sense amplifiers are arranged.

9. The semiconductor memory device according to claim 2, wherein a power supply is supplied to the plurality of drive circuits by connecting a power supply wiring and a first metal wiring to each other, which are formed in the sense amplifier region in which the sense amplifiers are arranged.

10. The semiconductor memory device according to claim 3, wherein a power supply is supplied to the plurality of drive circuits by connecting a power supply wiring and a first metal wiring to each other, which are formed in the sense amplifier region in which the sense amplifiers are arranged.

11. The semiconductor memory device according to claim 5, wherein a power supply is supplied to the plurality of drive circuits by connecting a power supply wiring and a first metal wiring to each other, which are formed in the sense amplifier region in which the sense amplifiers are arranged.

12. The semiconductor memory device according to claim 1, wherein the number of selection circuits connected to the local bit line selection signal line to which the bit line selection signal is supplied differs in a region that includes normal columns only that are used normally and a region that includes a redundancy column that is used as a substitute for a defective normal column which results when a normal column becomes defective, and a size of a transistor included in a respective one of the drive circuits varies in accordance with the number of selection circuits connected to the local bit line selection signal line.

13. The semiconductor memory device according to claim 1, wherein the plurality of drive circuits are made of transistors of a different type from that of the transistors included in the plurality of sense amplifier circuits.
